(19) United States
(12) Patent Application Publication
(10) Pub. No.: US 2021/0367135 A1
(43) Pub. Date: Nov. 25, 2021

(54) MEMS PIEZOELECTRIC TRANSDUCER HAVING OPTIMIZED CAPACITOR SHAPE

(71) Applicant: RDA MICROELECTRONICS (SHANGHAI) CO., LTD., Shanghai (CN)

(72) Inventors: Duan Feng, Shanghai (CN); Nianchu Hu, Shanghai (CN); Bin Jia, Shanghai (CN)

(21) Appl. No.: 16/605,863

(22) PCT Filed: Apr. 17, 2017
(86) PCT No.: PCT/CN2017/080744

§ 371 Date: Aug. 6, 2021

(51) Int. Cl. H01L 41/113; H01L 41/08

(52) U.S. Cl. CPC H01L 41/1132; B81B 2201/0285; H01L 41/0825

(57) ABSTRACT

The surface of the MEMS piezoelectric transducer that optimizes the capacitor shape of the present application is covered with m groups of capacitor (101, 102, 103, 104, 109), m being a natural number ≥2. When the MEMS piezoelectric transducer is loaded with a certain load, a stress of a region covered by any one of a first group of capacitors>a stress of a region covered by any one of a second group of capacitors> . . . >a stress of a region covered by any one of a (m−1)ₜₕ group of capacitors>a stress of a region covered by any one of a mₜₕ group of capacitors. Capacitors of the same group are connected in series and/or in parallel; capacitors of different groups are connected in series. The present application performs optimization design to the shape, position and number of the capacitor based on the stress distribution of the MEMS piezoelectric transducer when a certain load is loaded. It can significantly reduce the charge flow on the piezoelectric transducer due to uneven stress distribution, enhance the electromechanical transducing coefficient of the piezoelectric transducer as a whole, and improve output of the electrical signal of the transducer.

### TECHNICAL FIELD

The present application relates to a MEMS piezoelectric transducer, and more particularly (but not limited to) a piezoelectric transducer that converts vibration energy, acoustic energy, and the like in the environment into electrical energy.

### BACKGROUND

A transducer is a device that converts energy from one form into another, usually converts a signal of one form of energy into that of another. These forms of energy include electrical energy, mechanical energy, electromagnetic energy, light energy, chemical energy, acoustic energy, thermal energy, and the like.

A piezoelectric transducer is a device that interconverts mechanical energy and electrical energy with each other by utilizing a piezoelectric effect of a piezoelectric material. The piezoelectric effect includes a positive piezoelectric effect which converts mechanical energy into electrical energy and an inverse piezoelectric effect which converts electrical energy into mechanical energy.

A MEMS piezoelectric transducer is a micro-electromechanical transducer capable of converting mechanical energy in the environment into electrical energy via a positive piezoelectric effect and also capable of converting electrical energy into mechanical energy via an inverse piezoelectric effect. When used for converting mechanical energy into electrical energy, the MEMS piezoelectric transducer is usually used in the following two aspects: (1) energy harvesting which converts weak vibration energy in the environment into electrical energy so as to drive the electrical device to work and (2) a sensor which converts vibration or acoustical signals in the environment into electrical signals to output. Compared with the traditional capacitive transducing technology, the piezoelectric transducer has advantages of higher mechanical reliability, higher electromechanical transducing coefficient, not DC bias required. When used as a sensor, sensitivity of the piezoelectric transducer is higher and readout circuit of the piezoelectric transducer is simpler. In recent years, with the maturity of the preparation technology of a film piezoelectric material, more and more MEMS piezoelectric transducers have been invented and applied to our lives, such as piezoelectric energy harvesters, piezoelectric microphones, and piezoelectric ultrasonic fingerprint identification device.

The physical principle of the MEMS piezoelectric transducer for converting mechanical energy into electrical energy is that when a certain load is loaded to the piezoelectric transducer, the piezoelectric material constituting the transducer will be polarized due to a positive piezoelectric effect, positive and negative charges are produced on its two opposite surfaces, and the magnitude of the charge amount is linearly related to that of stress on the structure.

For a particular mechanical structure, when a certain load is loaded to its structure, the stress on the structural is not uniformly distributed, but fluctuates with the force condition of the structure and the geometrical shape of the structure. FIGS. 1A and 1B show a rectangular cantilever structure in which one end is fixedly supported and the remaining portions are suspended. FIG. 1A is a side view of the rectangular cantilever, wherein a thickness of the rectangular cantilever is uniform, and an exemplary load is applied uniformly from the top to the bottom on the upper surface of the rectangular cantilever. FIG. 1B is a top plan view of the rectangular cantilever, i.e., the rectangular cantilever is viewed along the direction of action of the illustrated load. FIGS. 1A and 1B show the stress distribution on the rectangular cantilever under a fixed load. The darker the color, the greater the stress, and the lighter the color, the smaller the stress. It may be found that the stress of the rectangular cantilever at a fixed support position is zero. At a boundary of the fixed support position and the suspended portion, the stress of the surface of the rectangular cantilever is the maximum. Along the X-axis direction, as the distance from the fixed support position increases, the stress of the surface of the rectangular cantilever becomes smaller and smaller, presenting a state of stress gradient distribution. The stress is zero at the end of the rectangular cantilever which is away from the fixed support position.

There is presented a linear correlation relationship between the magnitude of the charge amount produced under the positive piezoelectric effect and that of the stress on the structure, and thus the gradient distribution of the stress will cause the corresponding fluctuation of the charge produced on the surface of the piezoelectric material, and then the redistribution currents of the charge is formed in the electrode. Referring to FIGS. 2A and 2B, this is a piezoelectric transducer in a rectangular cantilever structure with a uniform thickness. FIG. 2A is a side view of a rectangular cantilever and FIG. 2B is a top view of a rectangular cantilever. The rectangular cantilever 100 has only one end fixedly supported on the side wall 110 and the remaining portions are suspended. The rectangular cantilever 100 includes a piezoelectric film layer 111 and a support layer 112. One upper electrode 113A is provided on the upper surface of the piezoelectric film layer 111. One lower electrode 113B is provided on the lower surface of the piezoelectric film layer 111. The upper electrode 113A and the lower electrode 113B substantially cover the entire regions of the upper surface and the lower surface of the piezoelectric film layer 111, respectively, and constitute the single capacitor of the piezoelectric transducer. The support layer 112 is located under the piezoelectric film layer 111 and configured to support the piezoelectric film layer 111 and the electrodes of the upper and lower surfaces thereof. On the surface of either electrode, the charge flows from a region of greater stress of the rectangular cantilever 100 to a region of smaller stress to form the redistribution currents of the charge. This flow of charge may adversely affect the output performance of the piezoelectric transducer, such as reducing the output power of the vibration energy harvester, reducing the sensitivity of the sensor, reducing the signal-to-noise ratio (SNR) of the sensor and so on.

In order to reduce the influence of the stress gradient distribution on the piezoelectric transducer, the conventional solution is shown in FIGS. 3A and 3B, which is another piezoelectric transducer of rectangular cantilever structure with a uniform thickness. FIG. 3A is a side view of a rectangular cantilever; FIG. 3B is a top view of a rectangular cantilever. The rectangular cantilever 100 has only one end fixedly supported on the side wall 110 and the remaining portions are suspended. The rectangular cantilever 100 includes a piezoelectric film layer 111 and a support layer 112. One upper electrode 114A is provided on the upper surface of the piezoelectric film layer 111. One lower electrode 114B is provided on the lower surface of the piezoelectric film layer 111. The upper electrode 114A and the lower electrode 114B cover only a partial region of the upper surface and the lower surface of the piezoelectric film layer 111, respectively, and preferably cover a region where the stress on the surface of the rectangular cantilever 100 is large, thereby constituting the single capacitor of the piezoelectric transducer. The support layer 112 is located under the piezoelectric film layer 111 and configured to support the piezoelectric film layer 111 and the electrodes of the upper and lower surfaces thereof. Since the coverage area of the effective capacitor is reduced so that it covers only a region with greater stress, the influence of the redistribution currents of charge on the output of the piezoelectric transducer may be reduced. However, this solution also has shortcomings, including: (1) wasting the structural area: directly discarding the transduction of the portion with smaller stress on the structure; (2) compared to the case where the electrode covers the entire surface, the capacitance value of the capacitor constituted by the electrode partially covering is smaller. Therefore, this solution is still not the optimum solution to solve the stress gradient distribution and can only partially improve the output performance of the piezoelectric transducer.

### Technical Problem

The technical problem to be solved by the present application is that when the MEMS piezoelectric transducer is loaded with a certain load, uneven stress distribution may occur, resulting in the charge generated under the positive piezoelectric effect flowing from a region with greater stress to a region with smaller stress to produce redistribution currents of the charge, which adversely affects the output performance of the piezoelectric transducer.

### Technical Solution

In order to solve the above technical problem, the surface of the MEMS piezoelectric transducer that optimizes the capacitor shape of the present application is covered with m groups of capacitor, m being a natural number ≥2. Each group of capacitors comprises either only one capacitor or a plurality of capacitors. When the MEMS piezoelectric transducer is loaded with a certain load, a stress of a region covered by any one of a first group of capacitors>a stress of a region covered by any one of a second group of capacitors> . . . >a stress of a region covered by any one of a (m−1)ₜₕ group of capacitors>a stress of a region covered by any one of a mₜₕ group of capacitors. Capacitors of the same group are connected in series and/or in parallel; capacitors of different groups are connected in series. This indicates that the capacitors are preferentially provided in a region where a stress of the MEMS piezoelectric transducer is largest or larger, at least two groups of capacitors cover the two regions of different ranges of stress on the surface of the MEMS piezoelectric transducer and at least two groups of capacitor being connected in series helps to reduce the redistribution currents of the charge on the electrodes.

Preferably, the areas of capacitor of the different groups are substantially the same, and the capacitors with substantially same areas have substantially the same capacitance values. Since different groups of capacitor are connected in series, each group of capacitors connected in series having substantially the same capacitance value will minimize the output impedance of the piezoelectric transducer.

Preferably, the entirety of all the capacitor substantially covers an entire surface of the piezoelectric transducer. If the gap between the capacitors and a small region above the fixed position of the piezoelectric transducer where the stress is zero are neglected, the surface of the piezoelectric transducer is substantially entirely covered by the capacitors. This can make full use of the stress in almost all regions of the piezoelectric transducer to produce electrical signals.

Preferably, the surface of piezoelectric transducer is divided into at least two regions according to the stress magnitude of the MEMS piezoelectric transducer when a certain load is loaded, and each region corresponds to a range of stress different from each other. Each region comprises either only one block or a plurality of blocks. The first group of capacitors is provided corresponding to a region of the maximum range of stress, the second group of capacitors is provided corresponding to a region of the second largest range of stress, and so on. Capacitors have at least two groups. This provides a convenient implementation for how to arrange capacitors in the MEMS piezoelectric transducer.

Preferably, in the at least two regions, if a certain region is one continuous block on the surface of the MEMS piezoelectric transducer, a group of capacitors corresponding to the region includes only one capacitor. If a certain region is a discrete plurality of blocks on the MEMS piezoelectric transducer, a group of capacitors corresponding to the region comprises a plurality of capacitors, each of which corresponds to one block. This also provides a convenient implementation for how to arrange capacitors in the MEMS piezoelectric transducer.

Further, the MEMS piezoelectric transducer further comprises a group of dummy capacitors. The group of dummy capacitors comprises either only one dummy capacitor or a plurality of dummy capacitors. When the MEMS piezoelectric transducer is loaded with a certain load, a stress of a region covered by any one of the mₜₕ group of capacitors>a stress of a region covered by any one of the dummy capacitors. The dummy capacitors do not participate in output of an electrical signal. This indicates that the dummy capacitors are preferentially provided in a region where the stress of the MEMS piezoelectric transducer is the minimum, and excluding these regions from output of the electrical signal helps to improve the output performance of the piezoelectric transducer.

Preferably, suspended electrodes are provided in a region covered by dummy capacitors, and the capacitors thus formed do not participate in output of the electrical signal. Alternatively, the electrodes can be not provided in the region. When electrodes are provided in the region covered by dummy capacitors, it is advantageous to adopt a uniform manufacturing process on the semiconductor material, and it is not necessary to adopt a special isolation process for the region covered by dummy capacitors. It is also feasible when electrodes are not provided in the region covered by dummy capacitors.

Preferably, the entirety of all capacitor and all dummy capacitors substantially covers the entire surface of the piezoelectric transducer. The surface of the piezoelectric transducer is substantially entirely covered by a capacitor or a dummy capacitor if the gap between the capacitor is ignored, in the case where the piezoelectric transducer contains a dummy capacitor. In this way, on one hand, it is possible to make full use of the stress of all the other regions except for a region of the minimum range of stress of the piezoelectric transducer to generate electrical signals; on the other hand, it avoids adverse effects of the noise of a region of the minimum range of stress and the like on the output performance of the piezoelectric transducer.

Preferably, the surface of piezoelectric transducer is divided into at least three regions according to the stress magnitude of the MEMS piezoelectric transducer when a certain load is loaded, and each region corresponds to a range of stress different from each other; each region comprises either only one block or a plurality of blocks; the first group of capacitors is provided corresponding to a region of the maximum range of stress, the second group of capacitors is provided corresponding to a region of the second largest range of stress, and so on; capacitors have at least two groups; the group of dummy capacitors is provided corresponding to a region of the minimum range of stress. This provides a convenient implementation for how to arrange capacitors in the MEMS piezoelectric transducer.

Preferably, in the at least three regions, if a certain region is one continuous block on the surface of the MEMS piezoelectric transducer, a group of capacitors corresponding to the region comprises only one capacitor, or a group of dummy capacitors corresponding to the region comprises only one dummy capacitor; if a certain region is a discrete plurality of blocks on the MEMS piezoelectric transducer, a group of capacitors corresponding to the region comprises a plurality of capacitors, each of which corresponds to one block; or a group of dummy capacitors corresponding to the region comprises a plurality of dummy capacitors, each of which corresponds to one block. This also provides a convenient implementation for how to arrange capacitors in the MEMS piezoelectric transducer.

Preferably, the MEMS piezoelectric transducer is either uniform in thickness or non-uniform in thickness; or is regular in shape or irregular in shape; the shape of the MEMS piezoelectric transducer includes at least a rectangular cantilever, a fan-shaped cantilever, a right-angled triangular cantilever, a square bilateral fixed support cantilever, and a square suspension film. According to the embodiments and the technical principles disclosed herein, it may be obtained that the scope applicable to the present application is not limited by whether the thickness is uniform and whether the shape is regular.

Preferably, the MEMS piezoelectric transducer contains only one layer of piezoelectric film layer, an electrode layer is disposed on both upper and lower surfaces of the piezoelectric film layer and a support layer is disposed above or below an overall structure.

Alternatively, the MEMS piezoelectric transducer includes two or more layers of piezoelectric film layers and the support layer is omitted, and an electrode layer is disposed on both upper and lower surfaces of each layer of the piezoelectric film layer. Alternatively, the MEMS piezoelectric transducer comprises two or more layers of piezoelectric film layers, an electrode layer is disposed on both upper and lower surfaces of each piezoelectric film layer and a support layer is disposed above or below or in the middle of the overall structure. This is a different implementation of the MEMS piezoelectric transducer, including the number of piezoelectric film layers, the number of electrode layers and the relative positional relationship of the support layers, all of which may vary.

Preferably, all electrode layers corresponding to the same region position in the MEMS piezoelectric transducer constitutes one capacitor or one dummy capacitor. Corresponding to different implementations of the MEMS piezoelectric transducer, if it contains two electrode layers, the two electrode layers corresponding to the same region position either constitute one capacitor or constitute one dummy capacitor. If it comprises three electrode layers, the three electrode layers corresponding to the same region position either constitute one capacitor or constitute one dummy capacitor. For the same region position, a capacitance value of a capacitor composed of the three electrode layers is approximately twice that of a capacitor composed of the two electrode layers, which is advantageous for improving the signal output of the piezoelectric transducer.

### Advantageous Effect

The present application performs optimization design to the shape, position and number of the capacitor based on the stress distribution of the MEMS piezoelectric transducer when a certain load is loaded, and connects different capacitor in series and/or in parallel according to the requirements of the device for output impedance, sensitivity and noise characteristics. The conventional MEMS piezoelectric transducer typically has only one capacitor and may cause redistribution currents of the charge in the electrode layer due to uneven stress distribution. The present application provides at least two groups of capacitor corresponding to at least two regions of different ranges of stress on the MEMS piezoelectric transducer, which can significantly reduce the charge flow on the piezoelectric transducer due to uneven stress distribution. In a region where the range of stress of the MEMS piezoelectric transducer is the minimum, the present invention also provides one group of dummy capacitors that does not participate in output of the electrical signal, which can enhance the electromechanical transducing coefficient of the piezoelectric transducer as a whole and improve output of the electrical signal of the transducer. For example, the output power of the vibration energy harvester is improved, the sensitivity of the sensor (such as a piezoelectric microphone) is increased, the signal-to-noise ratio of the sensor is increased, and the like.

### BRIEF DESCRIPTION OF THE DRAWINGS

FIG. 1A is a side view of a stress distribution of a rectangular cantilever.

FIG. 1B is a top plan view of a stress distribution of the rectangular cantilever as shown in FIG. 1A.

FIG. 2A is a side view of a piezoelectric transducer in a rectangular cantilever structure.

FIG. 2B is a top plan view of a piezoelectric transducer in a rectangular cantilever structure as shown in FIG. 2A.

FIG. 3A is a side view of a piezoelectric transducer in another rectangular cantilever structure.

FIG. 3B is a top plan view of a piezoelectric transducer in a rectangular cantilever structure as shown in FIG. 3A.

FIG. 4A is a top plan view of the first embodiment of a MEMS piezoelectric transducer provided by the present application.

FIG. 4B is a side view of the first implementation of the first embodiment as shown in FIG. 4A.

FIG. 4C is a side view of the second implementation of the first embodiment as shown in FIG. 4A.

FIG. 4D is a side view of the third implementation of the first embodiment shown in FIG. 4A.

FIG. 5A is a top plan view of the stress distribution of a fan-shaped cantilever.

FIG. 5B is a top plan view of the second embodiment of a MEMS piezoelectric transducer provided by the present application.

FIG. 6A is a top plan view of a stress distribution of a right triangle cantilever.

FIG. 6B is a top plan view of the third embodiment of a MEMS piezoelectric transducer provided by the present application

FIG. 7A is a top plan view of a stress distribution of a square bilateral fixed support cantilever.

FIG. 7B is a top plan view of the fourth embodiment of a MEMS piezoelectric transducer provided by the present application.

FIG. 8A is a top plan view of a stress distribution of a square suspension film.

FIG. 8B is a top plan view of the fifth embodiment of a MEMS piezoelectric transducer provided by the present application.

Reference numerals in the figures:
100—rectangular cantilever; 200—fan-shaped cantilever; 300—right-angled triangular cantilever; 400—square bilateral fixed support cantilever; 500—square suspension film; 101 to 104, 201 to 203, 301 to 303, 401 to 404, 501 to 505—capacitor; 109, 204, 304 to 306, 405, 506—dummy capacitor; 110, 120, 130—fixed support sidewalk 111, 121—piezoelectric film layer; 131A—upper piezoelectric film layer; 131B—lower piezoelectric film layer; 112, 122—support layer; 113A, 114A, 115A, 125A, 135A—upper electrode of the capacitor; 135B—middle electrode of the capacitor; 113B, 114B, 115B, 125B, 135C—lower electrode of the capacitor; 119A, 129A, 139A—upper electrode of the dummy capacitor; 139B—middle electrode of the dummy capacitor; 119B, 129B, 139B—lower electrode of the dummy capacitor.

### EMBODIMENTS

### Embodiment I

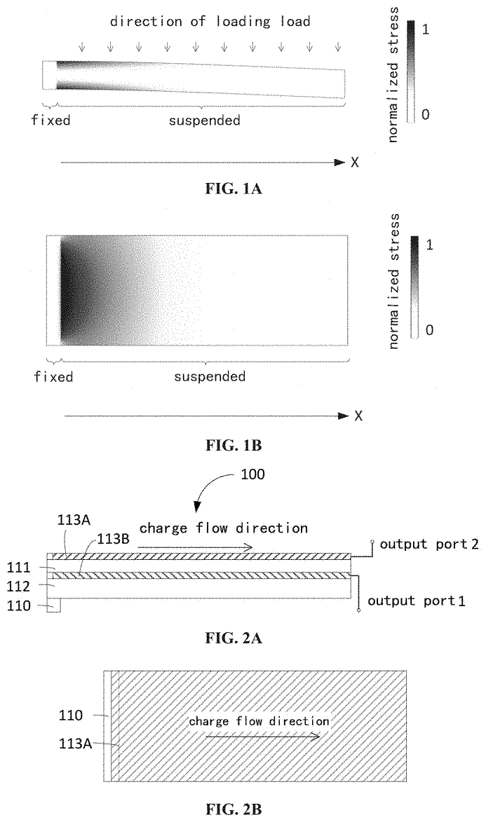

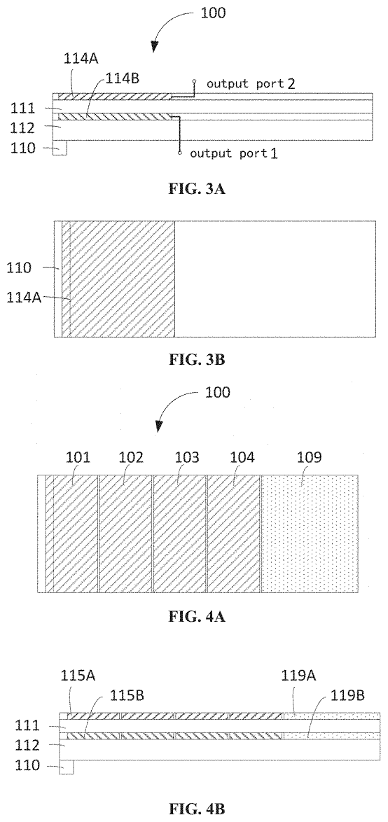

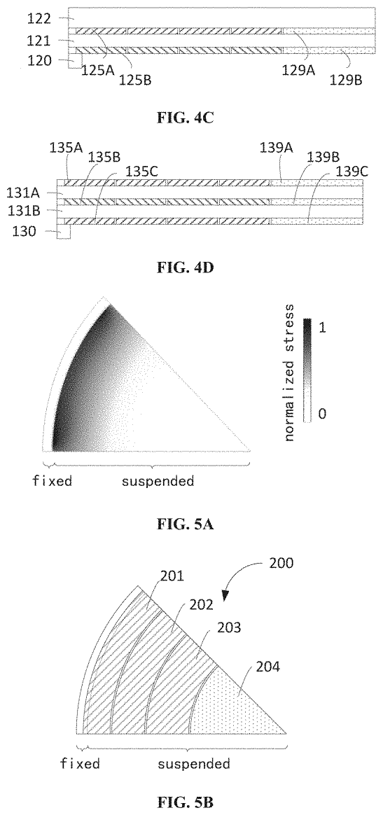

This is a MEMS piezoelectric transducer of a rectangular cantilever structure with a uniform thickness. FIG. 4A is a top plan view of a rectangular cantilever 100. The rectangular cantilever 100 is provided with four effective capacitors 101 to 104 and is further provided with a dummy capacitor 109. The four capacitors 101 to 104 belong to the first group, the second group, the third group and the fourth group of capacitors, respectively, and each of the four groups of capacitors include only one capacitor. A group of dummy capacitors only contain a dummy capacitor 109. As may be seen from FIGS. 1A and 1B, the stress of the rectangular cantilever 100 covered by the four capacitors 101 to 104 is successively decreased in a descent order, and the capacitor 101 covers a region (i.e., the boundary of the fixed support portion and the suspended parts) of the rectangular cantilever 100 where the stress is the maximum. The dummy capacitor 109 corresponds to a region of the rectangular cantilever 100 where the stress is the minimum. As shown in FIG. 1B, there is a partial region above the fixed support portion where the stress is zero, and this partial region is not covered with electrodes and may be regarded as another dummy capacitor; alternatively, this partial region may also be changed to be covered by an extension of the capacitor 101 instead. In an operating state, the four capacitors 101 to 104 are connected in series. The dummy capacitor 109 does not participate in output of the electrical signal.

Preferably, in a case where the total area of the effective capacitor remains constant, if different groups of capacitors 101 to 104 have the same or similar areas, they have the same or similar capacitance values. At this time, the piezoelectric transducer composed of the capacitors 101 to 104 in series has the minimum output impedance. Of course, the four different groups of capacitors 101 to 104 may also have different areas, but the output impedance of the piezoelectric transducer is larger when the total area of the effective capacitor is constant.

The first implementation of the first embodiment described above is illustrated in FIG. 4B which is a side view of the rectangular cantilever 100. The rectangular cantilever 100 has only one end fixedly supported on the side wall 110 and the remaining portions suspended. The rectangular cantilever 100 includes a piezoelectric film layer 111 and a support layer 112. Four upper electrodes 115A and one upper electrode 119A are provided on the upper surface of the piezoelectric film layer 111. Four lower electrodes 115B and one lower electrode 119B are provided on the lower surface of the piezoelectric film layer 111. The support layer 112 is located under the piezoelectric film layer 111 and configured to support the piezoelectric film layer 111 and the electrodes of the upper and lower surfaces thereof. The upper electrode 115A and the lower electrode 115B corresponding to a relevant position constitute a capacitor 101 in FIG. 4A, and other capacitors 102 to 104 in FIG. 4A are also constituted by the upper electrode 115A and the lower electrode 115B corresponding to the position of the same region. The upper electrode 119A constitutes the dummy capacitor 109 in FIG. 4A with the lower electrode 119B corresponding to a relevant position and the dummy capacitor 109 does not participate in output of the piezoelectric transducer.

Preferably, the upper electrode 115A and the lower electrode 115B corresponding to a relevant position have substantially the same shape and area; the upper electrode 119A and the lower electrode 119B corresponding to a relevant position also have substantially the same shape and area.

The second implementation of the first embodiment described above is shown in FIG. 4C which is a side view of the rectangular cantilever 100. The rectangular cantilever 100 has only one end fixedly supported on the side wall 120 and the remaining portions suspended. The rectangular cantilever 100 includes a piezoelectric film layer 121 and a support layer 122. Four upper electrodes 125A and one upper electrode 129A are provided on the upper surface of the piezoelectric film layer 111. Four lower electrodes 125B and one lower electrode 129B are provided on the lower surface of the piezoelectric film layer 111. The support layer 122 is located above the piezoelectric film layer 121 and configured to support the piezoelectric film layer 121 and the electrodes of the upper and lower surfaces thereof. The upper electrode 125A and the lower electrode 125B corresponding to a relevant position constitute a capacitor 101 in FIG. 4A, and other capacitors 102 to 104 in FIG. 4A are also constituted by the upper electrode 125A and the lower electrode 125B corresponding to the position of the same region. The upper electrode 129A constitutes the dummy capacitor 109 in FIG. 4A with the lower electrode 129B corresponding to a relevant position and the dummy capacitor 109 does not participate in output of the piezoelectric transducer.

Preferably, the upper electrode 125A and the lower electrode 125B corresponding to a relevant position have substantially the same shape and area, and the upper electrode 129A and the lower electrode 129B corresponding to a relevant position also have substantially the same shape and area.

A third implementation of the first embodiment above is illustrated in FIG. 4D which is a side view of the rectangular cantilever 100. The rectangular cantilever 100 has only one end fixedly supported on the side wall 130 and the remaining portions suspended. The rectangular cantilever 100 includes an upper piezoelectric film layer 131A and a lower piezoelectric film layer 131B. Four upper electrodes 135A and one upper electrode 139A are provided on the upper surface of the upper piezoelectric film layer 131A. Four middle electrodes 135B and one middle electrode 139B are provided between the upper piezoelectric film layer 131A and the lower piezoelectric film layer 131B. Four lower electrodes 135C and one lower electrode 139C are provided on the lower surface of the lower piezoelectric film layer 131B. The upper electrode 135A is electrically connected with the lower electrode 135C corresponding to a relevant position and constitutes a capacitor 101 in FIG. 4A with the middle electrode 135B corresponding to a relevant position. Other capacitors 102 to 104 in FIG. 4A are also composed of the upper electrode 135A, the middle electrode 135B and the lower electrode 135C corresponding to the positions of the same region, wherein the upper electrode 135A and the lower electrode 135C serve as one plate of the capacitor and the middle electrode 135B serves as another. The upper electrode 139A and the middle electrode 139B corresponding to a relevant position constitute the dummy capacitor 109 in FIG. 4A with the lower electrode 139C and the dummy capacitor 109 does not participate in output of the piezoelectric transducer.

Preferably, the upper electrode 135A and the middle electrode 135B and the lower electrode 135C corresponding to a relevant position have substantially the same shape and area; the upper electrode 139A and the middle electrode 139B and the suspended lower electrode 139C corresponding to a relevant position also have substantially the same shape and area.

Assuming that the capacitors in the above three implementations have the same shapes and sizes, the area of the plate formed by electrical conduction between the upper electrode and the lower electrode of the capacitor in FIG. 4D is twice the area of any plate of the capacitor in FIG. 4B or FIG. 4C. This indicates that a capacitance value of a capacitor in FIG. 4D is twice that in FIG. 4B or FIG. 4C, which is advantageous for increasing output of the piezoelectric transducer.

The above three implementations may deposit insulating materials or may not deposit any materials in a region where the upper and lower surfaces of the piezoelectric film layer 111 are not covered with the electrode, for example, in an electrode gap between any two capacitors. Taking FIG. 4B as an example, when the insulating material is deposited, the thickness thereof is preferably substantially equal to that of the electrode, at that time, the upper and lower surfaces of the piezoelectric film layer 111 are substantially kept flat. When no material is deposited, since the electrodes have a certain thickness, the upper and lower surfaces of the piezoelectric film layer 111 will appear stepped depressions in regions where the electrodes are not covered. At this time, a region where the lower surface of the piezoelectric film layer 111 not covered with the electrodes is in contact with the upper surface of the support layer 112 and a corresponding region of the upper surface of the support layer 112 renders, for example, a stepped projection.

The dummy capacitor 109 in the above three implementations are all covered with electrodes, and the dummy capacitors does not participate in output of the electrical signal. In other implementations, the dummy capacitor region may be covered by electrodes or may be covered without electrodes. When a group of dummy capacitors are composed of a plurality of dummy capacitors, some of the dummy capacitors may be covered with electrodes and the remaining may not.

The three implementations of the first embodiment given above may be summarized as follows: the MEMS piezoelectric transducer of the present application may include only one layer of the piezoelectric film layer, both surfaces of the piezoelectric film layer are provided with electrode layers and a support layer is provided above or below the overall structure. Alternatively, the MEMS piezoelectric transducer of the present application may also include two or more layers of piezoelectric film layers and the support layer is omitted, and electrode layers are disposed on both surfaces of each layer of the piezoelectric film layer. Further, it is foreseeable that the MEMS piezoelectric transducer of the present application may further comprise two or more layers of piezoelectric film layers, electrode layers are disposed on both surfaces of each layer of the piezoelectric film layer, and a support layer is provided above or below or in the middle of the overall structure, which has still the same principle as the three implementations disclosed above.

### Embodiment II

This is a MEMS piezoelectric transducer of a fan-shaped cantilever structure with a uniform thickness. FIGS. 5A and 5B show a fan-shaped cantilever structure in which only a circular arc is fixedly supported and the remaining portions are suspended. FIG. 5A is a top plan view of the fan-shaped cantilever showing the stress distribution on the fan-shaped cantilever under a fixed load. The darker the color, the greater the stress, and the lighter the color, the smaller the stress. It may be found that the stress of the fan-shaped cantilever at the fixed support position is zero. At the boundary of the fixed support position and the suspended portion, the stress of the surface of the fan-shaped cantilever is the maximum. Along any radial direction, as the distance from the fixed support position increases, the stress of the surface of the fan-shaped cantilever becomes smaller and smaller, showing a state of stress gradient distribution. Until the fan-shaped cantilever is far from the end of the fixed support position, that is, the center of the circle, the stress is zero. FIG. 5B is also a top plan view of the fan-shaped cantilever 200. The fan-shaped cantilever 200 is provided with three effective capacitors 201 to 203 and is further provided with a dummy capacitor 204. The three capacitors 201 to 203 belong to the first group, the second group and the third group of capacitors, respectively, and each of the three groups of capacitors include only one capacitor. A group of dummy capacitors only contains a dummy capacitor 204. As may be seen from FIG. 5A, the stress in a region of the fan-shaped cantilever 200 covered by the three capacitors 201 to 203 are successively decreased in a descent order and the capacitor 201 covers a region (i.e., the boundary of the fixed support portion and the suspended portion) of the fan-shaped cantilever 200 where the stress is the maximum. The dummy capacitor 204 corresponds to a region of the fan-shaped cantilever 200 where the stress is the minimum. As shown in FIG. 5A, there is a partial region above the fixed support portion where the stress is zero, and this partial region is not covered with electrodes and may be regarded as another dummy capacitor; alternatively, this partial region may also be changed to be covered by an extension of the capacitor 201 instead. In an operating state, the three capacitors 201 to 203 are connected in series. The dummy capacitor 204 does not participate in output of the electrical signal.

Preferably, the three capacitors in different groups 201 to 203 have the same or similar areas such that they have the same or similar capacitance values. This ensures that the piezoelectric transducer comprising capacitors 201 to 103 connected in series has the minimum output impedance in a case where the total area of the effective capacitor is constant.

### Embodiment III

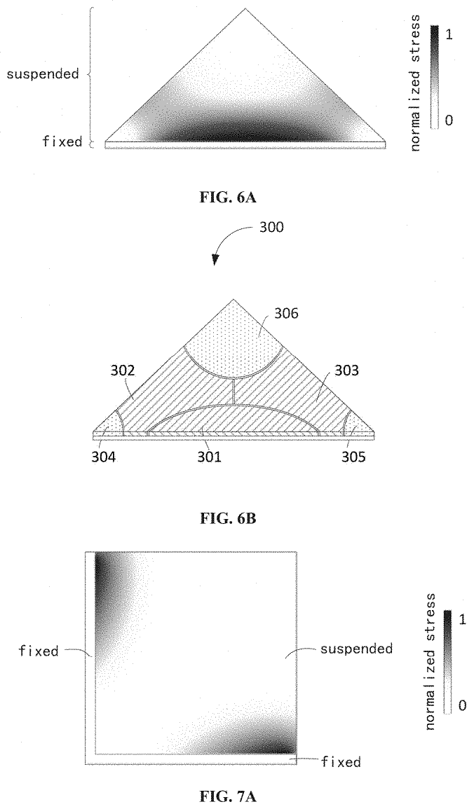

This is a MEMS piezoelectric transducer of a right-angled triangular cantilever structure with a uniform thickness. FIGS. 6A and 6B show a right-angled triangular cantilever structure in which only a hypotenuse is fixedly supported and the remaining portions are suspended. FIG. 6A is a top plan view of the right-angled triangular cantilever showing the stress distribution on the fan-shaped cantilever under a fixed load. The darker the color, the greater the stress, and the lighter the color, the smaller the stress. It may be found that the stress of the right-angled triangular cantilever at a fixed support position is zero. At the partial boundaries of the fixed support position and the suspended portion, the stress of the surface of the right-angled triangular cantilever is the maximum. FIG. 6B is also a top plan view of the right-angled triangular cantilever 300. The right-angled triangular cantilever 300 is provided with three effective capacitors 301 to 303 and is further provided with three dummy capacitors 304 to 306. The capacitor 301 belongs to the first group which only contains one capacitor. The capacitors 302 and 303 belong to the second group which comprises two capacitors. The dummy capacitors 304 to 306 belong to a group of dummy capacitors which comprises three dummy capacitors. As may be seen from FIG. 6A, the stress condition of a region of the right-angled triangular cantilever 300 covered by the three capacitors 301 to 303 is as follows: a stress of a region covered by the capacitor 301>a stress of a region covered by the capacitor 302≈a stress of a region covered by the capacitor 303. The capacitor 301 covers a region (i.e., partial boundaries of the fixed support position and the suspended portion) of the right-angled triangular cantilever 300 where the stress is the maximum. The dummy capacitors 304 to 306 cover the three blocks with the minimum stress on the right-angled triangular cantilever 300 and the stresses of the three blocks are substantially the same. As shown in FIG. 6A, there is a partial region above the fixed support portion where the stress is zero, and this partial region is not covered with the electrode and may be regarded as another dummy capacitor; alternatively, this partial region may also be changed to be covered by extensions of the capacitors 301 to 303 and the dummy capacitors 304 to 305, respectively. In an operating state, the capacitors 302 and 303 may be connected in series or in parallel, and the capacitors connected in series or in parallel with the capacitor 301 may only be connected in series due to different ranges of stress belong to different groups. None of the dummy capacitor 304 to 306 participates in output of the electrical signal.

Preferably, capacitors 301 through 303 have the same or similar areas such that they have the same or similar capacitance values. At this time, the three capacitors 301 to 303 are sequentially connected in series to maximize the output electrical signal.

Preferably, the area of the first group of capacitors is substantially equal to that of the second group of capacitors, i.e. the area of the capacitor 301 is approximately the sum of the areas of the capacitors 302 and 303. At this time, the capacitors 302 and 303 are connected in parallel (or merged into the same capacitor without cutting) to form a parallel capacitor having a large capacitance value. The parallel capacitor is in series with the capacitor 301. The capacitor 301 belongs to the first group of capacitors, the parallel capacitor belongs to the second group of capacitors and the areas of the capacitors of different groups are substantially the same, so that the minimum output impedance of the piezoelectric transducer may be obtained without changing the total area of the effective capacitor. Further preferably, the capacitors 302 and 303 have the same or similar area, and the area of the capacitor 301 is approximately twice that of the capacitor 302.

### Embodiment IV

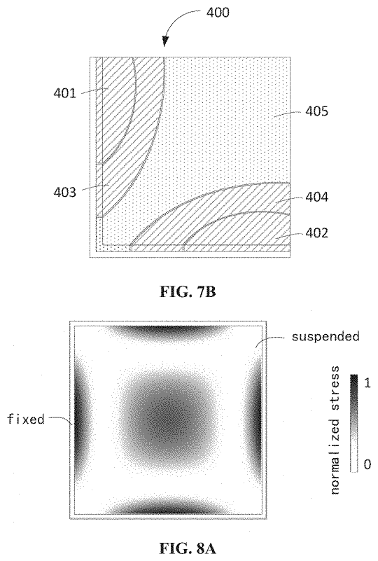

This is a MEMS piezoelectric transducer of a square cantilever structure with a uniform thickness. FIGS. 7A and 7B show a square cantilever structure in which only two adjacent sides are fixedly supported and the remaining portions are suspended. FIG. 7A is a top plan view of the square cantilever showing the stress distribution on the square cantilever under a fixed load; the darker the color, the greater the stress, and the lighter the color, the smaller the stress. It may be found that the stress of the square cantilever at a fixed support position is zero. At partial boundaries of the fixed support position and the suspended portion, the stress of the surface of the square cantilever is the maximum. FIG. 7B is also a top plan view of the square cantilever 400. The square cantilever 400 is provided with four effective capacitors 401 to 404 and is further provided with a dummy capacitor 405. Capacitors 401 and 402 belong to the first group of capacitors, capacitor 403 and 404 belong to the second group of capacitors, and each of the two groups of capacitor comprises two capacitors. A group of dummy capacitors only contains a dummy capacitor 405. As may be seen from FIG. 7A, a stress condition of a region of the square cantilever 400 covered by the four capacitors 401 to 404 is as follows: a stress of a region covered by the capacitor 401 a stress of a region covered by the capacitor 402>a stress of a region covered by the capacitor 403 a stress of a region covered by the capacitor 404. The capacitors 401 and 402 cover a region (i.e., partial boundaries of the fixed support position and the suspended portion) of the square cantilever 400 where stress is the maximum. The dummy capacitor 405 covers a region of the square cantilever 400 where stress is the minimum. As shown in FIG. 7A, there is a partial region above the fixed support portion where the stress is zero, and this partial region is not covered with the electrode and may be regarded as another dummy capacitor; alternatively, this partial region may also be changed to be covered by extensions of the capacitors 401 to 404 and the dummy capacitor 405, respectively. In an operating state, the capacitors 401 and 402 are connected in series and/or in parallel, the capacitors 403 and 404 are connected in series and/or in parallel, and the two capacitors formed are connected in series. The dummy capacitor 405 does not always participate in output of the electrical signal.

Preferably, the four capacitors 401 to 404 have the same or similar area such that they have the same or similar capacitance values, and the capacitors 401 to 404 are sequentially connected in series to maximize the output electrical signal.

Preferably, the area of the first group of capacitors is substantially equal to that of the second group of capacitors, i.e., the sum of the areas of the capacitors 401 and 402 is substantially equal to that of the capacitor 403 and 404. At this time, the capacitors 401 and 402 are connected in parallel to obtain a first parallel capacitor having a large capacitance value. The capacitors 403 and 404 are connected in parallel to obtain a second parallel capacitor having a large capacitance value. The first parallel capacitor belongs to the first group of capacitors, the second parallel capacitor belongs to the second group of capacitors, and the areas of the capacitors of different groups are substantially the same. Hence, the minimum output impedance of the piezoelectric transducer may be obtained in a case where the total area of the effective capacitor remains constant. Further preferably, the capacitors 401 to 404 have the same or similar areas.

### Embodiment V

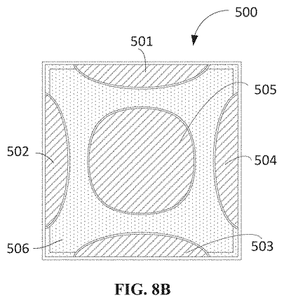

This is a MEMS piezoelectric transducer of a square suspension film structure with a uniform thickness. FIGS. 8A and 8B show a square suspension film structure in which only four sides of the square are fixedly supported and the remaining portions are suspended. FIG. 8A is a top plan view of the square suspension film showing the stress distribution on the square suspension film under a fixed load; the darker the color, the greater the stress, and the lighter the color, the smaller the stress. It may be found that the stress of the square suspension film at the fixed support position is zero. At partial boundaries of the fixed support position and the suspended portion, the stress of the surface of the square suspension film is the maximum. FIG. 8B is also a top plan view of the square suspension film 500. The square suspension film 500 is provided with five effective capacitors 501 to 505 and is further provided with a dummy capacitor 506. Capacitors 501 to 504 belong to the first group of capacitors which is composed of four capacitors. Capacitor 505 belongs to the second group of capacitors which contains only one capacitor. A group of dummy capacitors only contains a dummy capacitor 506. A stress condition of a region of the square suspension film 500 covered by the five capacitors 501 to 505 is as follows: a stress of a region covered by the capacitor 501≈a stress of a region covered by the capacitor 502≈a stress of a region covered by the capacitor 503≈a stress of a region covered by the capacitor 504>a stress of a region covered by the capacitor 505. The capacitors 501 and 504 cover a region (i.e., partial boundaries of the fixed support position and the suspended portion) of the square cantilever 500 where stress is the maximum. The dummy capacitor 506 covers a region of the square cantilever 500 where stress is the minimum. As shown in FIG. 8A, there is a partial region above the fixed support portion where the stress is zero, and this partial region is not covered with the electrode and may be regarded as another dummy capacitor; alternatively, this partial region may also be changed to be covered by extensions of the capacitors 501 to 504 and the dummy capacitor 506, respectively. In an operating state, the capacitors 501 to 504 may be connected in series and/or in parallel in any forms, the formed capacitors are connected in series with the capacitor 505. The dummy capacitor 506 does not always participate in output of the electrical signal.

Preferably, the five capacitors 501 to 505 have the same or similar areas such that they have the same or similar capacitance values, and the capacitors 501 to 505 are sequentially connected in series to maximize the output electrical signal.

Preferably, the area of the first group of capacitors is substantially equivalent to that of the second group of capacitors. For example, the sum of the areas of the capacitor 501 to 504 is approximately equivalent to the area of the capacitor 505. At this time, the capacitors 501 to 504 are connected in parallel, and the formed capacitors are connected in series with the capacitor 505. Further preferably, the four capacitors 501 to 504 have the same or similar area, and the area of the capacitor 505 is approximately four times that of the capacitor 501. As another example, the sum of the areas of any two of the capacitor 501 through 504 (referred to as A and B) is substantially equivalent to that of another two (referred to as C and D) while being substantially equivalent to the area of the capacitor 505. At this time, the capacitors A and B are connected in parallel, the capacitors C and D are connected in parallel, and the two capacitors formed are connected in series with the capacitor 505. Further preferably, the four capacitors 501 to 504 have the same or similar area, and the area of the capacitor 505 is approximately twice that of the capacitor 501. In summary, the capacitors 501 to 504 are connected in series and/or in parallel, and the formed capacitors are connected in series again with capacitor 505. The capacitor formed by capacitors 501 to 504 connected in any form belongs to the first group of capacitors, and the capacitor 505 belongs to the second group of capacitors. The capacitors of different groups have substantially the same areas. Hence, the minimum output impedance of the piezoelectric transducer may be obtained in a case where the total area of the effective capacitor remains constant.

The implementations of the above Embodiment II to Embodiment V may refer to embodiment I, which may be one layer of piezoelectric film layer and a support layer above or below it, or two or more layers of piezoelectric film and the support layer being omitted, or alternatively two or more layers of piezoelectric film layers and a support layer provided above or below or in the middle of the overall structure.

According to the above five embodiments, it may be found that the MEMS piezoelectric transducer provided by the present application optimizes the shape of the capacitor, which is mainly embodied in the following aspects.

First, the present application designs the position, number, and shape of the capacitor according to the stress distribution of the MEMS piezoelectric transducer when a certain load is loaded. In particular, in a region where the stress of the MEMS piezoelectric transducer is greater, the necessity to provide a capacitor is higher; and vice versa. Therefore, the capacitor is preferentially provided in a region where the stress of the MEMS piezoelectric transducer is largest and larger.

Although the above five embodiments all have a dummy capacitor provided on the MEMS piezoelectric transducer, the dummy capacitor is not necessarily required by the present application. If the MEMS piezoelectric transducer of the present application omits the dummy capacitor, then the entirety of all the effective capacitors substantially covers the entire surface of the piezoelectric transducer. If the MEMS piezoelectric transducer of the present application contains a dummy capacitor, then the entirety of all the effective capacitors and the dummy capacitor substantially covers the entire surface of the piezoelectric transducer.

If a dummy capacitor is provided on the MEMS piezoelectric transducer, since it covers a region of the piezoelectric transducer with the minimum stress, this region typically has a noise level higher than the level of a signal or at the same level as the signal, and the dummy capacitor does not participate in the signal output, which is in favor of improving the output performance of the piezoelectric transducer. Otherwise, if no dummy capacitor is provided on the MEMS piezoelectric transducer, it means that a region with the minimum stress also participates in the signal output, which will degrade the output performance of the piezoelectric transducer.

Preferably, in a region where the stress of the MEMS piezoelectric transducer is smaller, the necessity of providing a dummy capacitor is higher, and vice versa. Therefore, the dummy capacitor is preferentially provided in a region where the stress of the MEMS piezoelectric transducer is the minimum.

Preferably, a capacitor is provided in a region where the stress of the MEMS piezoelectric transducer is the maximum; a dummy capacitor is provided in a region where the stress of the MEMS piezoelectric transducer is the minimum; either a capacitor or a dummy capacitor may be provided in other regions of the MEMS piezoelectric transducer.

It may be found from the above five embodiments that each of capacitors or dummy capacitor covers a part of the surface of the MEMS piezoelectric transducer, and the stress of the surface of the covered region is not a specific value but a stress range. When discussing the stress of the first region>the stress of the second region, it actually refers to any stress value within the range of stress in the first region>any stress value within the range of stress in the second region.

Preferably, the surface of the MEMS piezoelectric transducer is divided into two or more regions according to the stress magnitude of the MEMS piezoelectric transducer when a certain load is loaded, and each region corresponds to a range of stress different from each other. The first group of capacitors is provided corresponding to a region of the maximum range of stress, the second group of capacitors is provided corresponding to a region of the second largest range of stress, and so on. The capacitors have at least two groups. If a certain region is a continuous block on the surface of the MEMS piezoelectric transducer, the corresponding group of capacitors preferably contains only one capacitor. If a certain region is a discrete plurality of blocks on the surface of the MEMS piezoelectric transducer, the corresponding group of capacitors is composed of a plurality of capacitors, each of which preferably corresponds to one block. Alternatively, one block on the surface of the MEMS piezoelectric transducer may also be provided as at least two capacitors which may be connected in series and/or in parallel.

Further preferably, the surface of the MEMS piezoelectric transducer is divided into three or more regions according to the stress magnitude of the MEMS piezoelectric transducer when a certain load is loaded, and each region corresponds to a range of stress different from each other. The first group of capacitors is provided corresponding to a region of the maximum range of stress, the second group of capacitors is provided corresponding to a region of the second largest range of stress, and so on. The group of dummy capacitors is provided corresponding to a region of the minimum range of stress. Capacitors have at least two groups. If a certain region is a continuous block on the surface of the MEMS piezoelectric transducer, the corresponding group of capacitors preferably only contains one capacitor, or the corresponding group of dummy capacitors preferably contains only one dummy capacitor. If a certain region is a discrete plurality of blocks on the MEMS piezoelectric transducer, the corresponding group of capacitors comprises a plurality of capacitors, each of which preferably corresponds to one block; or the corresponding group of dummy capacitors comprises a plurality of dummy capacitors, each of which preferably corresponds to one block. Alternatively, one block on the surface of the MEMS piezoelectric transducer may also be provided as at least two capacitors which may be connected in series and/or in parallel; or may be provided as at least two dummy capacitors, none of which participating in output of the electrical signal.

For example, the stress value of the MEMS piezoelectric transducer when loaded with a certain load is normalized to between 0 and 1; a region where the stress value is between 0.75 and 1 is called the first region, a region where the stress value is between 0.5 and 0.75 is called the second region, a region where the stress value is between 0.25 and 0.5 is called the third region and a region where the stress value is between 0 and 0.25 is called the fourth region. Each region may be a contiguous block or composed of a plurality of isolated blocks. One group of dummy capacitors is provided in the fourth region of the minimum range of stress, and three groups of capacitors are respectively provided in the first region, the second region and the third region. Capacitors of the same group are connected in series and/or in parallel while capacitors of different groups are connected in series.

Second, at least two groups of effective capacitors are provided in one MEMS piezoelectric transducer. The number, shape and area of the effective capacitors may be determined according to the requirements of the actual circuit configuration for output impedance, sensitivity of the piezoelectric transducer and the noise.

First of all, in a case where the total area of the effective capacitors remains constant, the capacitors connected in parallel will make the output impedance of the piezoelectric transducer small and the capacitors connected in series will make the output impedance of the piezoelectric transducer large. The greater the number of the capacitors connected in series, the larger the output impedance of the piezoelectric transducer and the greater the noise intensity, but the greater the output electrical signal and the higher the sensitivity of the device; and vice versa. Capacitors with the same or similar stress in the coverage region or within the same stress range, that is, capacitors of the same group may be connected in series or in parallel.

Capacitors with significantly different stresses in the coverage region or within different ranges of stress, i.e. capacitors of different groups may only be connected in series. If capacitors of different groups are connected in parallel, the redistribution currents of the charge will still occur on the electrodes of these capacitors coverage regions, and thus the object of the present invention cannot be achieved.

Secondly, in a case where the total area of effective capacitor remains constant, when capacitors of different groups are connected in series, and if the respective capacitor participating in series connection has substantially the same capacitance value, the output impedance of the piezoelectric transducer will be made small; if the respective capacitor participating in series connection has significantly different capacitance value, the output impedance of the piezoelectric transducer will be made large. Hence, the areas of the capacitors of different groups are preferably the same. Considering that each group of capacitors may be composed of a plurality of capacitors, the connection between the plurality of capacitors may be in serial and/or in parallel, so the preferred areas of the respective capacitor and the mutual ratios are determined based on the capacitance values after each group of capacitors is actually connected and the connection method within the groups.

Third, the dummy capacitor may select to provide the electrodes according to the requirements of the mechanical strength and the resonant frequency of the MEMS piezoelectric transducer in the actual conditions, and the provided electrodes do not participate in output of the electrical signal. Alternatively, the dummy capacitor may not be provided with electrodes.

The area of the dummy capacitor may be determined according to the requirements of the circuit configuration for output impedance, sensitivity of the transducer and the noise.

Fourth, although all the above five embodiments relate to cantilevers or suspended film structures with uniform thickness, the MEMS piezoelectric transducer with uneven thickness still applicable because the same technical principle is employed. Although all the above five embodiments relate to the MEMS piezoelectric transducer in a regular shape, the MEMS piezoelectric transducer in an irregular shape is still applicable because the same technical principle is still employed.

The above is only preferred embodiments of the present application and is not intended to limit the present application. For those skilled in the art, various changes and modifications may be made to the present application, but any modifications, equivalent substitutions, improvements and the like made within the spirit and principle of the present application are intended to be included within the scope of protection of the present application.

### INDUSTRIAL APPLICABILITY

The present application may be applied to an electronic device for converting mechanical energy into electrical energy (electrical signals) such as a piezoelectric vibration energy harvester, a piezoelectric microphone, or the like.

What is claimed is:

1. A MEMS piezoelectric transducer having an optimized capacitor shape, wherein
a surface of the MEMS piezoelectric transducer is covered with m groups of capacitors, m being a natural number greater than or equal to 2;
each group of capacitors comprises either only one capacitor or a plurality of capacitors;
when the MEMS piezoelectric transducer is loaded with a certain load, a stress of a region covered by any one of a first group of capacitors>a stress of a region covered by any one of a second group of capacitors> . . . >a stress of a region covered by any one of a (m−1)ₜₕ group of capacitors>a stress of a region covered by any one of a mₜₕ group of capacitors;
capacitors of the same group are connected in series and/or in parallel; and
capacitors of different groups are connected in series.

2. The MEMS piezoelectric transducer having an optimized capacitor shape according to claim 1, wherein areas of the capacitors of different groups are substantially the same and capacitors with substantially same areas have substantially the same capacitance values.

3. The MEMS piezoelectric transducer having an optimized capacitor shape according to claim 1, wherein the entirety of all the capacitors substantially covers an entire surface of the piezoelectric transducer.

4. The MEMS piezoelectric transducer having an optimized capacitor shape according to claim 1, wherein
the surface of piezoelectric transducer is divided into at least two regions according to a stress magnitude of the MEMS piezoelectric transducer when a certain load is loaded, and each region corresponds to a range of stress different from each other;
each region comprises either only one block or a plurality of blocks;
the first group of capacitors is provided corresponding to a region of the maximum range of stress, the second group of capacitors is provided corresponding to a region of the second largest range of stress, and so on; and
capacitors have at least two groups.

5. The MEMS piezoelectric transducer having an optimized capacitor shape according to claim 4, wherein
in the at least two regions, if a certain region is one continuous block on the surface of the MEMS piezoelectric transducer, a group of capacitors corresponding to the region comprises only one capacitor; and
if a certain region is a discrete plurality of blocks on the MEMS piezoelectric transducer, a group of capacitors corresponding to the region comprises a plurality of capacitors, each of which corresponds to one block.

6. The MEMS piezoelectric transducer having an optimized capacitor shape according to claim 1, wherein
the MEMS piezoelectric transducer further comprises a group of dummy capacitors;
the group of dummy capacitors comprises either only one dummy capacitor or a plurality of dummy capacitors;
when the MEMS piezoelectric transducer is loaded with a certain load, a stress of a region covered by any one of the mₜₕ group of capacitors is greater than a stress of a region covered by any one of the dummy capacitors; and
the dummy capacitors do not participate in output of an electrical signal.

7. The MEMS piezoelectric transducer having an optimized capacitor shape according to claim 6, wherein a region covered by dummy capacitors is provided with an electrode, or not provided with the electrode.

8. The MEMS piezoelectric transducer having an optimized capacitor shape according to claim 6, wherein the entirety of all capacitors and all dummy capacitors substantially covers the entire surface of the piezoelectric transducer.

9. The MEMS piezoelectric transducer having an optimized capacitor shape according to claim 6, wherein
the surface of piezoelectric transducer is divided into at least three regions according to a stress magnitude of the MEMS piezoelectric transducer when a certain load is loaded, and each region corresponds to a range of stress different from each other;
each region comprises either only one block or a plurality of blocks;
the first group of capacitors is provided corresponding to a region of the maximum range of stress, the second group of capacitors is provided corresponding to a region of the second largest range of stress, and so on;
capacitors have at least two groups; and
the group of dummy capacitors is provided corresponding to a region of the minimum range of stress.

10. The MEMS piezoelectric transducer having an optimized capacitor shape according to claim 9, wherein
in the at least three regions, if a certain region is one continuous block on the surface of the MEMS piezoelectric transducer, a group of capacitors corresponding to the region comprises only one capacitor or a group of dummy capacitors corresponding to the region comprises only one dummy capacitor;
if a certain region is a discrete plurality of blocks on the MEMS piezoelectric transducer, a group of capacitors corresponding to the region comprises a plurality of capacitors, each of which corresponds to one block; or a group of dummy capacitors corresponding to the region comprises a plurality of dummy capacitors.

11. The MEMS piezoelectric transducer having an optimized capacitor shape according to claim 1, wherein
the MEMS piezoelectric transducer is either uniform in thickness or non-uniform in thickness; or is regular in shape or irregular in shape; and
the shape of the MEMS piezoelectric transducer includes at least a rectangular cantilever, a fan-shaped cantilever, a right-angled triangular cantilever, a square bilateral fixed support cantilever and a square suspension film.

12. The MEMS piezoelectric transducer having an optimized capacitor shape according to claim 1, wherein
the MEMS piezoelectric transducer comprises only one layer of piezoelectric film layer, an electrode layer is disposed on both upper and lower surfaces of the piezoelectric film layer, and a support layer is disposed above or below an overall structure;
alternatively, the MEMS piezoelectric transducer includes two or more layers of piezoelectric film layers and the support layer is omitted and an electrode layer is disposed on both upper and lower surfaces of each layer of the piezoelectric film layer; or
alternatively, the MEMS piezoelectric transducer comprises two or more layers of piezoelectric film layers, an electrode layer is disposed on both upper and lower surfaces of each piezoelectric film layer, and a support layer is disposed above or below or in the middle of the overall structure.

13. The MEMS piezoelectric transducer having an optimized capacitor shape according to claim 12, wherein in the MEMS piezoelectric transducer, all electrode layers corresponding to the same region position constitute one capacitor or one dummy capacitor.
